(19) United States
(12) Patent Application Publication
(10) Pub. No.: US 2008/0061359 A1
(43) Pub. Date: Mar. 13, 2008

(54) Dual charge storage node with undercut gate oxide for deep sub-micron memory cell

(76) Inventors: Chungho Lee, Sunnyvale, CA (US); Hiroyuki Kinoshita, San Jose, CA (US); Zoran Krivokapic, Santa Clara, CA (US); Wei Zheng, Santa Clara, CA (US); Mark S. Chang, Los Altos, CA (US); Rinji Sugino, San Jose, CA (US); Chi Chang, Saratoga, CA (US)

Correspondence Address: WAGNER, MURABITO & HAO LLP, Third Floor, Two North Market Street, San Jose, CA, 95113, US

(21) Appl. No.: 11/702,847

(22) Filed: Feb. 5, 2007

Related U.S. Application Data
(60) Provisional application No. 60/765,351, filed on Feb. 4, 2006.

(51) Int. Cl. H01L 29/792; H01L 21/336

(52) U.S. Cl. 257/324; 438/287; 257/E21.423; 257/E29.309

(57) ABSTRACT

An embodiment of the present invention is directed to a memory cell. The memory cell includes a stack formed over a substrate. The stack includes a gate oxide layer and an overlying polycrystalline silicon layer. The stack further includes first and second undercut regions formed under the polycrystalline silicon layer and adjacent to the gate oxide layer. The memory cell further includes a first charge storage element formed in the first undercut region and a second charge storage element formed in the second undercut region.

### CLAIM OF PRIORITY UNDER 35 U.S.C. §119

This application claims priority to U.S. Provisional Patent Application No. 60/765,351 entitled “PROCESS FOR FABRICATING DUAL CHARGE STORAGE NODE WITH UNDERCUT GATE OXIDE FOR DEEP SUB-MICRON MEMORY CELL AND RESULTING STRUCTURE” filed Feb. 4, 2006, and assigned to the assignee hereof and hereby expressly incorporated by reference herein.

### BACKGROUND

1. Field

Embodiments of the present invention generally relate to the field of semiconductor devices. More particularly, embodiments relate to memory storage cells.

2. Background

In recent years, dual bit memory cells, such as those employing MirrorBit® technology developed by Spansion, Inc., have been developed. As the name suggests, dual bit memory cells double the intrinsic density of a flash memory array by storing two physically distinct bits on opposite sides of a memory cell. Ideally, reading or programming one side of a memory cell occurs independently of whatever data is stored on the opposite side of the cell.

FIG. 1A illustrates a conventional dual-bit memory cell 100. Conventional dual bit memory cell 100 typically includes a substrate 110 with source/drain regions 120 implanted therein, a first oxide layer 130 above the substrate 110, a continuous charge trapping layer 140, a second oxide layer 150, and a poly layer 160. The bottom oxide layer 130 is also commonly referred to as a tunnel oxide layer.

Programming of a dual bit memory cell 100 can be accomplished, for example, by hot electron injection. Hot electron injection involves applying appropriate voltage potentials to the gate, source, and drain of the cell 100 for a specified duration until the charge trapping layer 140 accumulates charge. While for simplicity, charge is typically thought of as being stored in a fixed location (i.e., the edges) of charge trapping layer 140, in reality the location of the trapped charge for each node falls under a probability curve, such as curves 170 and 175. For the purposes of this discussion the bit associated with curve 170 shall be referred to as the “normal bit” and the bit associated with curve 175 shall be referred to as the “complementary bit”. It should be appreciated from FIG. 1A that the memory cell 100 illustrated therein is reasonably large, such that the two sides can be fairly localized and well separated.

FIG. 1B illustrates a conventional dual bit memory cell 105 having a smaller process geometry than the memory cell 100 of FIG. 1A. FIG. 1B illustrates that as the cell gets smaller, the distribution curves 170 and 175 stay the same, resulting in an overlap of the curves 170 and 175. Such an overlap in these regions can result in the contamination of one bit by its neighboring bit. This is also known as complementary bit disturb.

FIG. 2 graphically illustrates complementary bit disturb in a conventional memory cell having a continuous charge trapping layer. FIG. 2 illustrates the example of when the normal bit has been programmed, but the complement your bit has not. In such a case, the normal bit should read “0” and the complementary bit should read “1”. Whether or not a bit is programmed is reflected by a delta in the threshold voltage associated with that bit. In conventional dual bit memory cells, programming of a normal bit also results in a shift of the Vₜ of the complementary bit. For example, in a memory cell having a channel length L1, changing the Vₜ of the normal bit by X results in a change of the Vₜ of the complementary bit of Y. As the cell size gets smaller, resulting in a shorter channel length (e.g., L2), the disturbance increases, even before the bits physically touch each other. Thus, conventional dual bit memory cells do not have adequate protection against physical contamination of one bit by its neighboring bit, as well as program disturb in general.

### SUMMARY

An embodiment of the present invention is directed to a memory cell. The memory cell includes a stack formed over a substrate. The stack includes a gate oxide layer and an overlying polycrystalline silicon layer. The stack further includes first and second undercut regions formed under the polycrystalline silicon layer and adjacent to the gate oxide layer. The memory cell further includes a first charge storage element formed in the first undercut region and a second charge storage element formed in the second undercut region.

Thus, embodiments provide for dual storage node memory cells with physical separation of the storage nodes by an insulator. Such separation of the storage nodes greatly reduces program disturb between the two storage nodes, which is a critical issue as process geometries continue to decrease. As a result, embodiments are able to achieve geometries beyond 100 nm technology.

### BRIEF DESCRIPTION OF THE DRAWINGS

FIG. 1A illustrates a conventional dual-bit memory cell.

FIG. 1B illustrates a conventional dual bit memory cell having a smaller process geometry than the memory cell of FIG. 1A.

FIG. 2 graphically illustrates complementary bit disturb in a conventional memory cell having a continuous charge trapping layer.

FIG. 3 illustrates a cross-sectional view of an exemplary semiconductor device, in accordance with various embodiments of the present invention.

FIG. 4 illustrates selective etching of undercut regions in the semiconductor device, in accordance with various embodiments of the present invention.

FIG. 5 illustrates formation of a tunnel oxide layer on the semiconductor device, in accordance with various embodiments of the present invention.

FIG. 6 illustrates formation of a charge trapping layer on the semiconductor device, in accordance with various embodiments of the present invention.

FIG. 7 illustrates removal of a portion of the charge trapping layer on the semiconductor device, in accordance with various embodiments of the present invention.

FIG. 8 illustrates formation of sidewall spacers on the semiconductor device, in accordance with various embodiments of the present invention.

FIG. 9 illustrates formation of bit lines in the semiconductor device, in accordance with various embodiments of the present invention.

FIG. 10 illustrates oxide filling in the semiconductor device, in accordance with various embodiments of the present invention.

FIG. 11 illustrates removal of hard masks and excess oxide from the semiconductor device, in accordance with various embodiments of the present invention.

FIG. 12 illustrates formation of a polysilicon layer on the semiconductor device, in accordance with various embodiments of the present invention.

FIG. 13 illustrates a flowchart a process for fabricating a semiconductor memory cell having at least two charge storage elements, in accordance with various embodiments of the present invention.

FIG. 14 illustrates a flowchart foreign method of forming a charge storage element in an undercut region, in accordance with various embodiments of the present invention.

FIG. 15 shows a block diagram of a conventional portable telephone, upon which embodiments can be implemented.

FIG. 16 illustrates advantages of a memory cell according to one embodiment over conventional memory cells designs, with respect to program disturb.

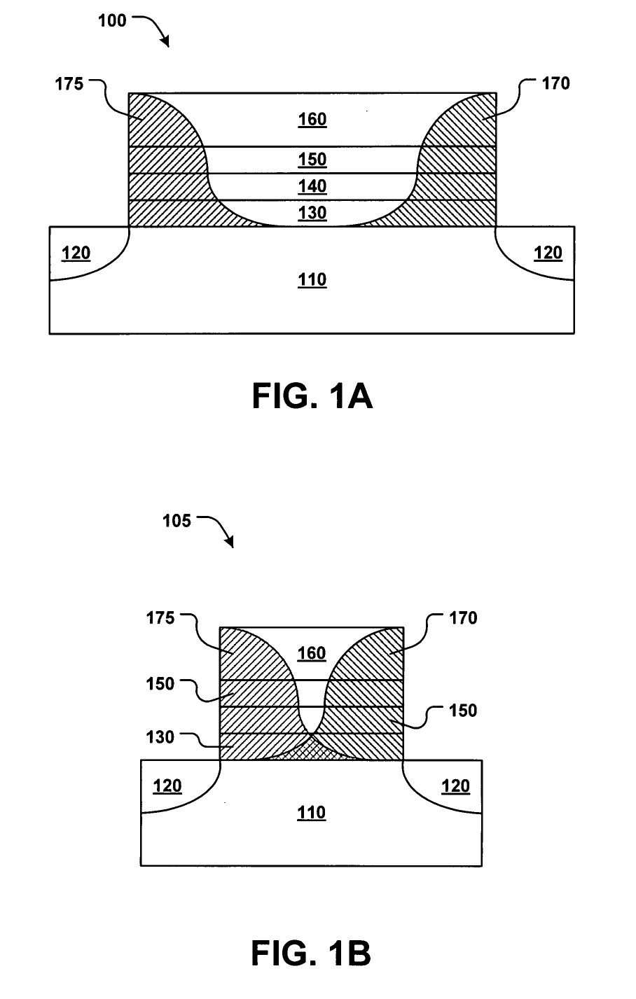

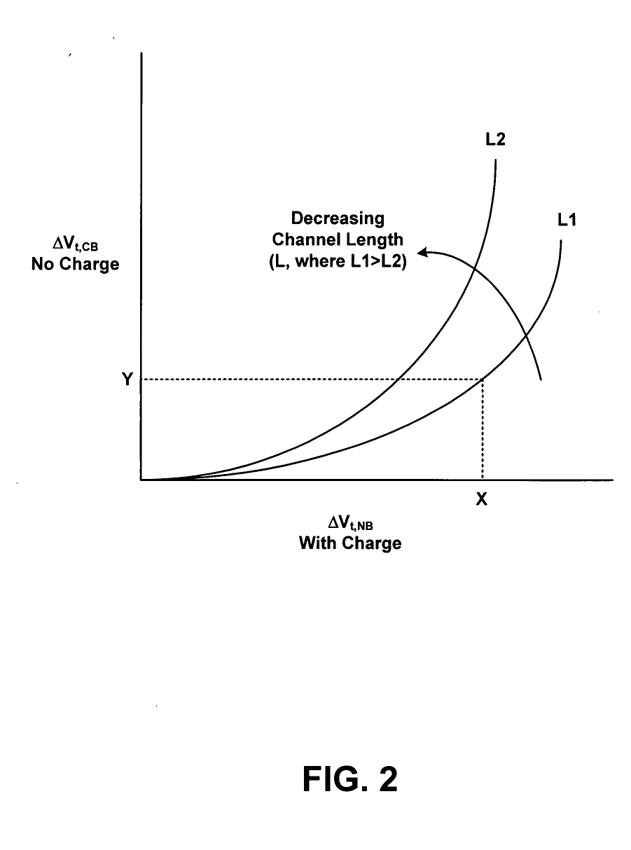

### DETAILED DESCRIPTION

The present invention will now be described in detail with reference to a various embodiments thereof as illustrated in the accompanying drawings. In the following description, specific details are set forth in order to provide a thorough understanding of the present invention. It will be apparent, however, to one skilled in the art, that the present invention may be practiced without using some of the implementation details set forth herein. It should also be understood that well known operations have not been described in detail in order to not unnecessarily obscure the present invention.

Briefly stated, embodiments reduce the likelihood of program disturb in a dual bit memory cell through physical separation of the charge storage nodes by forming a charge trapping regions in undercut regions of a gate oxide, thereby preventing charge contamination between the storage nodes. Because two separate charge storage regions are used, rather than one continuous charge storage layer, the separate charge storage nodes are insulated from each other.

### Exemplary Memory Cell in Accordance With an Embodiment

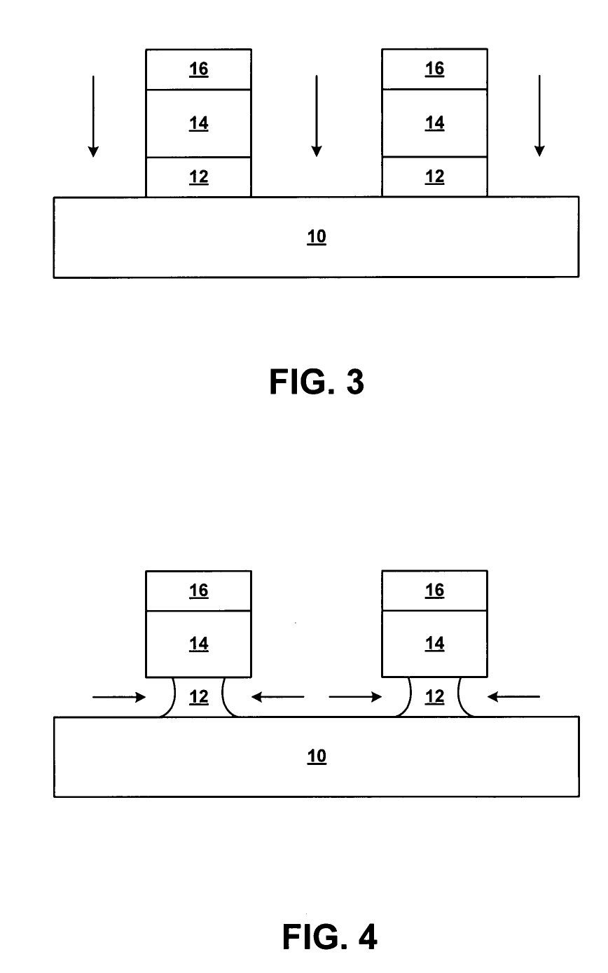

FIG. 3 illustrates a cross-sectional view of an exemplary semiconductor device, in accordance with various embodiments of the present invention. FIG. 3 shows a substrate 10 after etching an overlying gate oxide layer 12, polysilicon layer 14, and a hard mask 16, to expose surface areas for the fabrication of bit lines. It should be appreciated that the hard mask 16 may be a number of materials, including silicon nitride and the like. In one embodiment, the gate oxide 12 has a thickness on the order of 20-500 angstroms. Likewise, in one embodiment, the polysilicon layer 14 as a thickness on the order of 200-2000 angstroms.

As shown in FIG. 4, the gate oxide layer 12 is selectively etched to form first and second undercut regions on either side of the gate oxide layer 12 and under the polysilicon layer 14. In one embodiment, the widths of the first and second undercut regions are in the range of 50-500 angstroms. In one embodiment, the selective etch is performed by a wet etch process. For example, the wet edge may be a diluted HF etch, a chemical oxide removal (COR) etch, or the like.

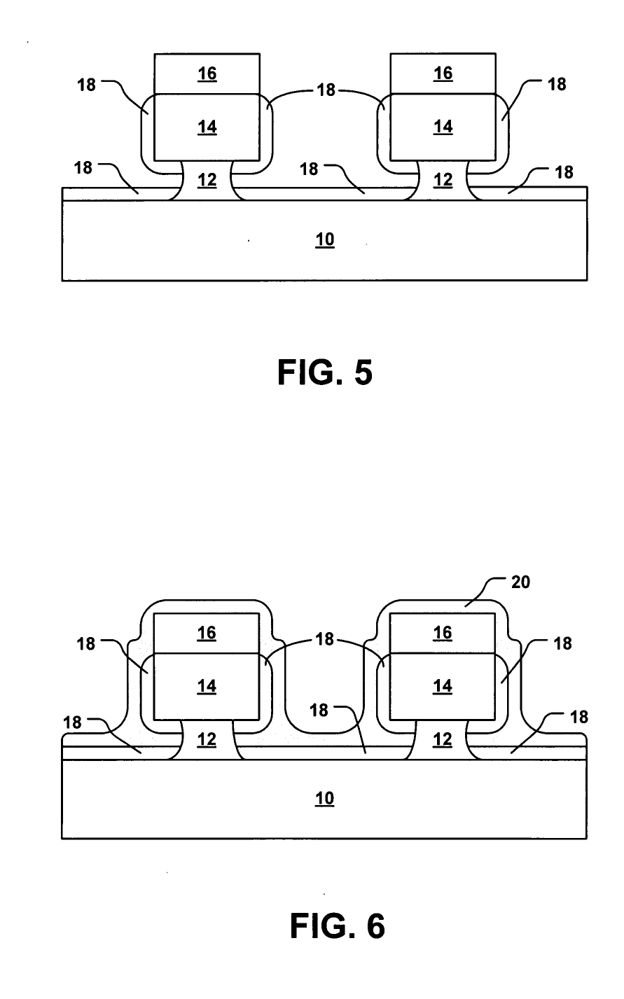

As shown in FIG. 5, a tunnel oxide layer 18 is then formed over the substrate 10 and the exposed regions of the polysilicon layer 14. It should be appreciated that the tunnel oxide layers 18 may be formed in a number of ways. For example, the tunnel oxide layer 18 may be formed by growing, by plasma oxidation, by chemical vapor deposition, or the like. In one embodiment, the tunnel oxide layer 18 is on the order of 10-100 angstroms thick. In other embodiments, other thickness may be used for the tunnel oxide layer 18. It should be appreciated at this point that the first and second undercut regions now contain two oxide layers separated by empty space.

As shown in FIG. 6, a layer of charge trapping material 20 is formed over the tunnel oxide layer 18. The layer of charge trapping material 20 is formed such that it fills the remainder of the first and second undercut regions. In one embodiment, in order to avoid any seam void during the undercut filling, multiple cycles of partial deposition and partial etch may be performed.

The charge trapping material 20 may be selected from a number of materials including, but not limited to, silicon nitride (SiN), silicon rich nitride (SiRN), polysilicon, high-K materials, and any combination thereof. It should be appreciated by one of skill in the art that although polysilicon and nitride materials may be used, the properties of the two materials are very different. For example, polysilicon is a conductor, which means that an electron may freely move throughout the material. By contrast, nitrides such as SiN and SiRN are insulators, wherein the location of a given electron stays relatively constant.

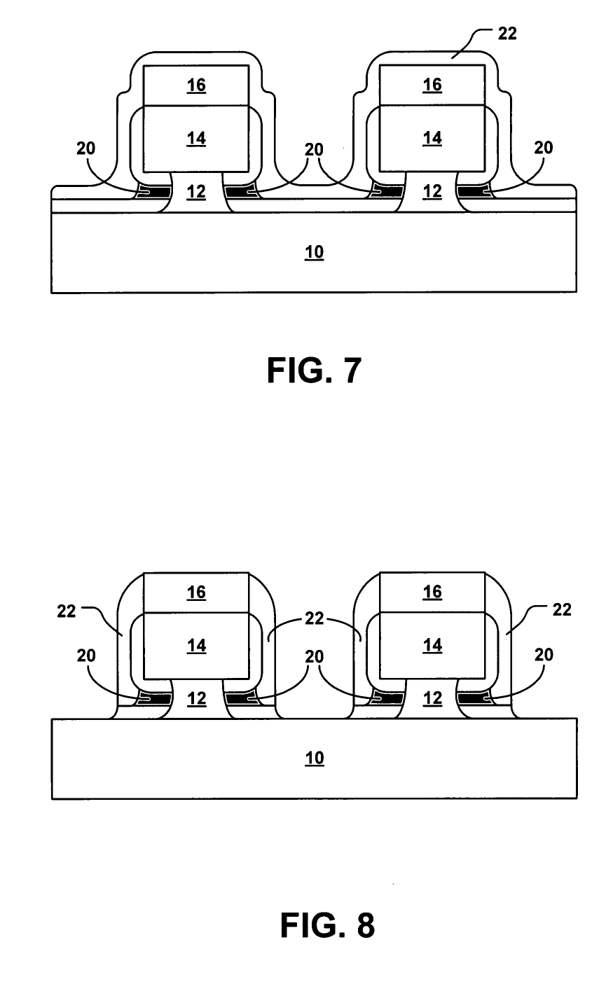

As shown in FIG. 7, the charge trapping material 20 is then removed, except for the portions in the first and second undercut regions. It should be appreciated that this may be achieved in a number of ways. For example, in one embodiment, the charge trapping material 20 is removed by a dry etch. The charge trapping material 20 may also be removed by a wet etch or any combination of wet and dry etch. In another embodiment, the charge trapping material 20 is carefully oxidized with a well-controlled process such that only the portions of the charge trapping material 20 in the first and second undercut regions remain. The oxidation may be thermal or plasma oxidation, for example. Regardless, the result is two physically isolated charge trapping regions 20 at each memory cell. In other words, the charge trapping regions 20 are insulated from each other by the oxide materials 12, 18, 22.

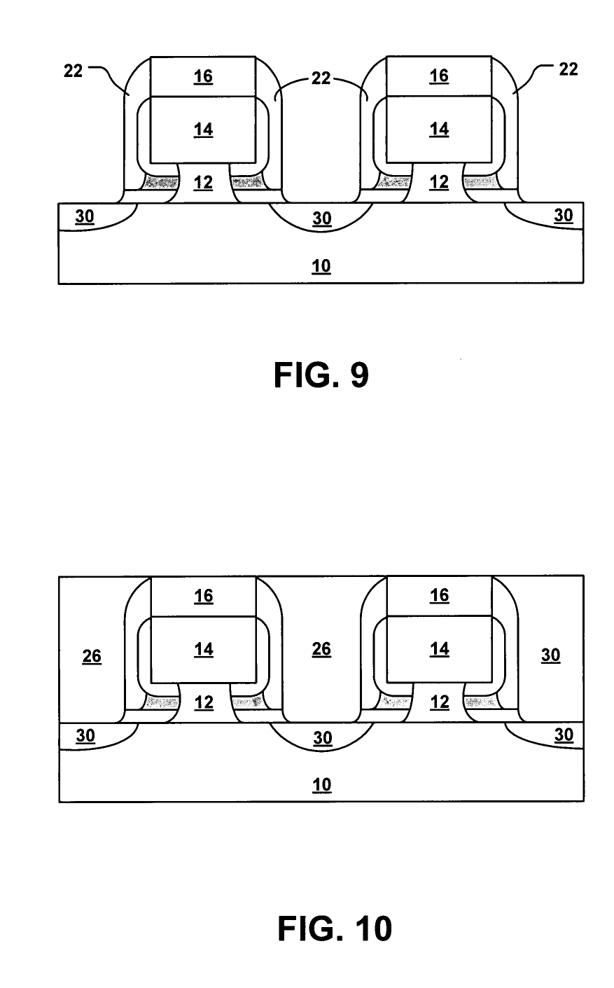

As shown in FIG. 8, the oxide layer 22 is etched to form sidewall spacers 22 around the periphery of the polysilicon layer 14. Thereafter, bit lines are formed in the substrate 10 by ion implantation using the sidewall spacers 22 as masks, as shown in FIG. 9. The gaps above the bit lines 30 and between the sidewall spacers 22 are then filled with silicon oxide 26, as shown in FIG. 10.

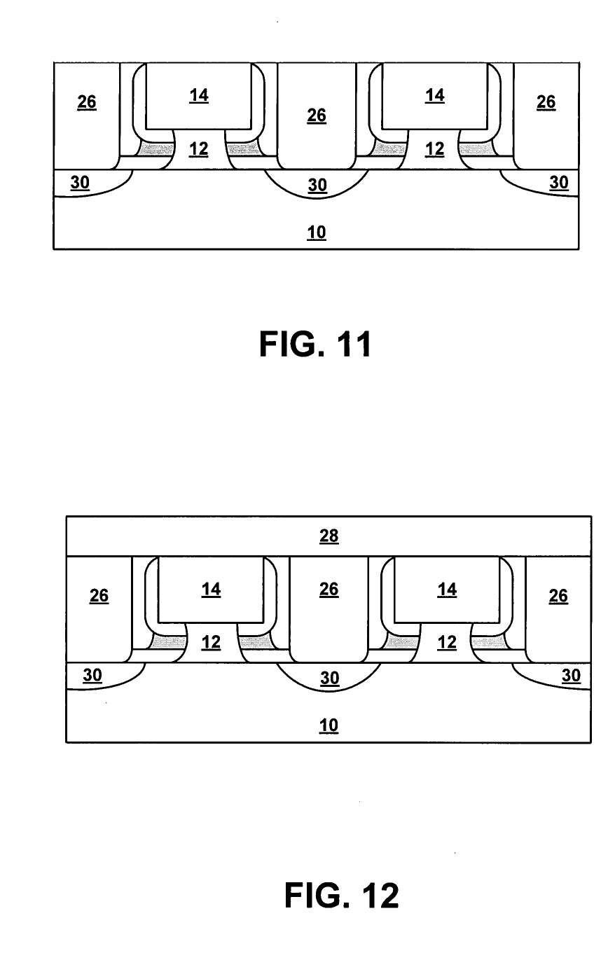

As shown in FIG. 11, the hard masks 16 and any surplus oxide material 26 are removed. In one embodiment, this is achieved by a chemical mechanical processing (CMP) polish. Thereafter, a second polysilicon layer 28 is deposited over the structure, as shown in FIG. 12. In one embodiment, the polysilicon layer 28 is on the order of 200-2000 angstroms thick. In other embodiments, other thicknesses of the polysilicon layer 28 may be employed. The second polysilicon layer 28 is then selectively masked and etched to form the word lines of the memory array.

### Exemplary Methods of Fabrication According to Various Embodiments

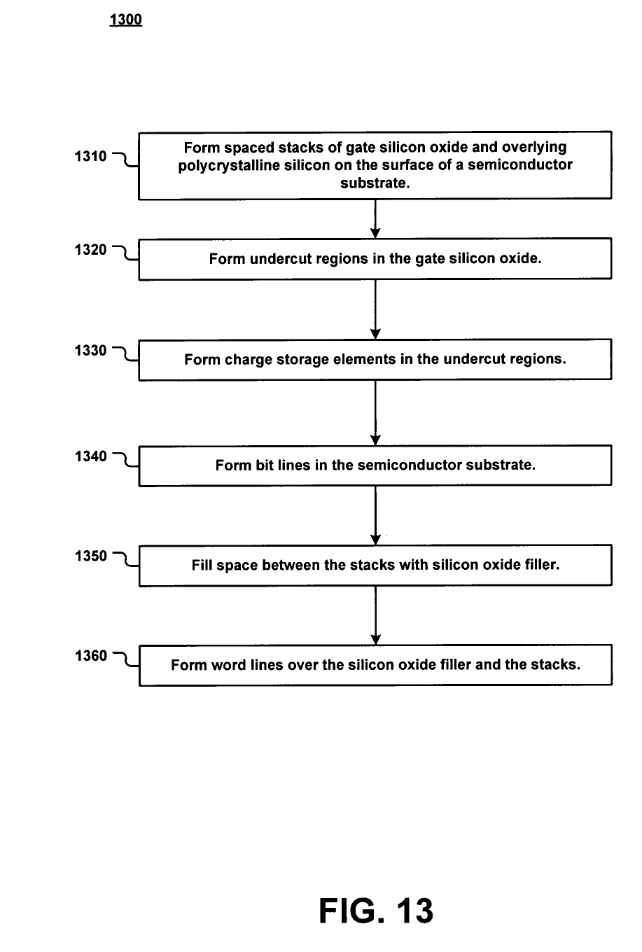

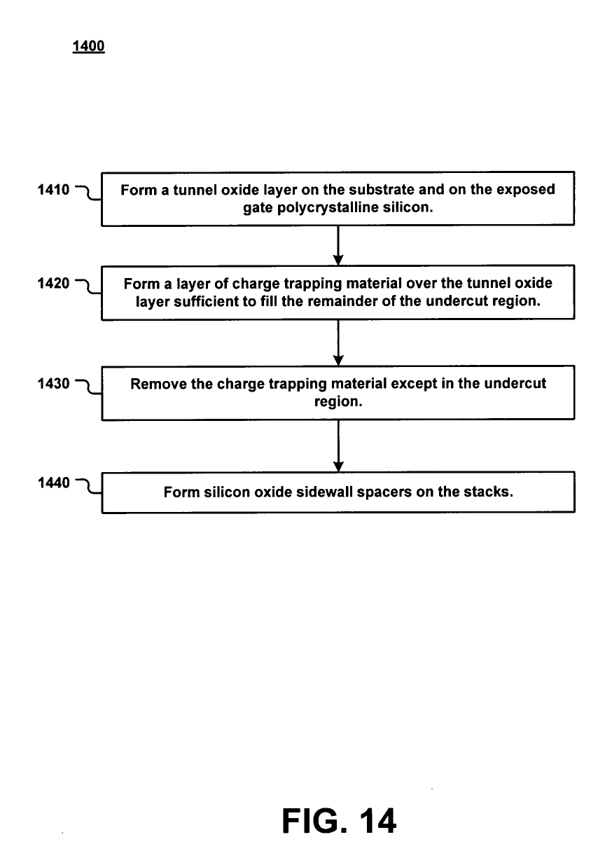

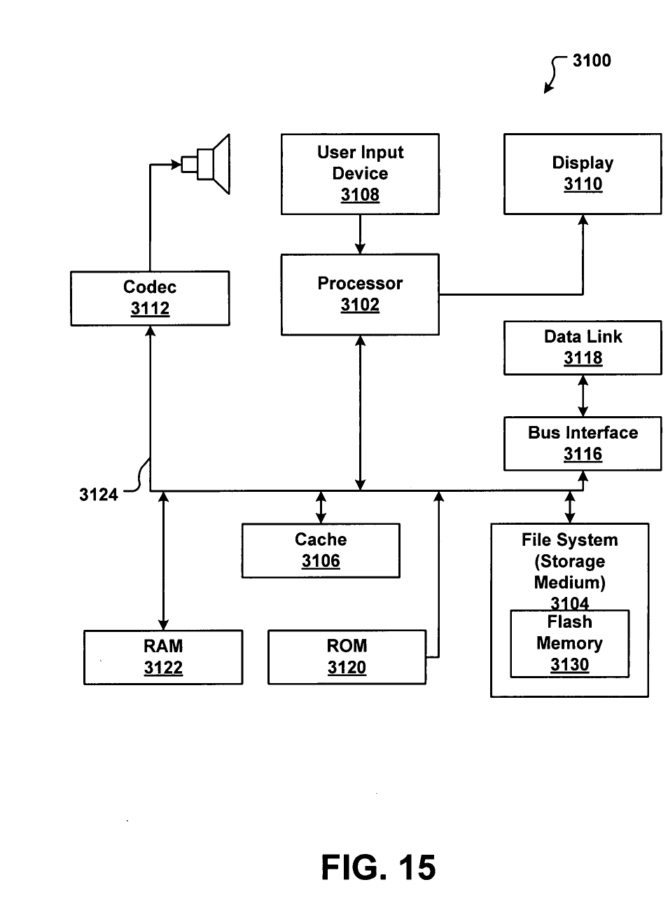

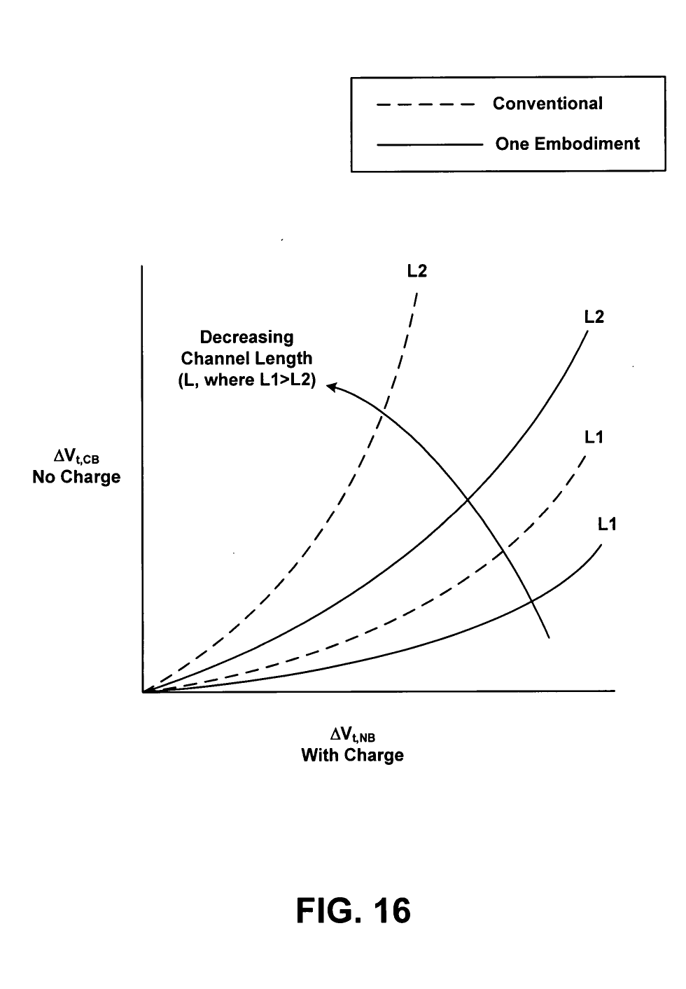

The following discussion sets forth in detail processes of fabrication according to various embodiments. With reference to FIGS. 13-14, flowcharts 1300 and 1400 each illustrate example fabrication steps used and various embodiments. Although specific steps are disclosed in flowcharts 1300 and 1400, such steps are examples. That is, embodiments are well suited to using various other steps or variations of the steps recited in flowcharts 1300 and 1400. It is appreciated that the steps in flowcharts 1300 and 1400 may be performed in an order different than presented, and that not all of the steps in flowcharts 1300 and 1400 may be performed.

FIG. 13 illustrates a flowchart 1300 a process for fabricating a semiconductor memory cell having at least two charge storage elements, in accordance with various embodiments of the present invention. At block 1310, spaced stacks of gate silicon oxide 12 and overlying polycrystalline silicon 14 are formed on the surface of a semiconductor substrate 10. In one embodiment, this is achieved by forming a layer of gate silicon oxide 12 on the substrate, forming a layer of polycrystalline silicon 14 over the gate silicon oxide 12, forming masks 16 over portions of the polycrystalline silicon 14, and etching to expose portions of the substrate 10.

At block 1320, undercut regions are formed in the gate silicon oxide 12. This may be achieved, for example, by a diluted HF etch, a chemical oxide removal (COR), or the like. At block 1330, charge storage elements are formed in the undercut regions. It should be appreciated that this may be achieved in a number of ways. For example, FIG. 14 illustrates a flowchart 1400 foreign method of forming a charge storage element in an undercut region, in accordance with various embodiments of the present invention. At block 1410, a tunnel oxide layer 18 is formed on the substrate 10 on the exposed gate polycrystalline silicon 14. Block 1420 then involves forming a layer of charge trapping material 20 over the tunnel oxide layer 18 sufficient to fill the remainder of the undercut region. The charge trapping material 20 may be selected from a number of materials including, but not limited to, silicon nitride (SiN), silicon rich nitride (SiRN), polysilicon, high-K materials, and any combination thereof. In one embodiment, in order to avoid any seam void during the undercut filling, multiple cycles of partial deposition and partial etch may be performed. The charge trapping material 20 is then removed except for portions in the undercut region (block 1430). At block 1440, silicon oxide sidewall spacers 22 are formed on the stacks sufficient to cover any remaining exposed portions of the charge trapping material 20. This may be achieved, for example, by forming a silicon oxide layer and etching to form the sidewall spacers 22 around the periphery of the polysilicon layer 14. Thus, using this technology, physically separate and isolated charge storage elements may be created.

With reference again to FIG. 13, block 1340 involves forming bit lines 30 in the semiconductor substrate 10. In one embodiment, this is accomplished by implanting the bit lines 30 while using the sidewall spacers 22 as masks. The remaining space between the stacks is then filled with silicon oxide filler 26 (block 1350). Subsequently, word lines are formed over the silicon oxide filler 26 and the stacks (block 1360). This may involve, for example, polishing down the hard masks 16 and portions of the silicon oxide sidewall spacers 22 and the silicon oxide filler 26, depositing a polysilicon layer 28, and etching the polysilicon layer 28 to form the word lines.

### Exemplary Operating Environments According to One Embodiment

Embodiments generally relate to semiconductor devices. More particularly, embodiments provide for a nonvolatile storage device having a dual bit memory cell with physically separated storage nodes. In one implementation, the various embodiments are applicable to flash memory and devices that utilize flash memory.

Flash memory is a form of non-volatile memory that can be electrically erased and reprogrammed. As such, flash memory, in general, is a type of electrically erasable programmable read only memory (EEPROM).

Like Electrically Erasable Programmable Read Only Memory (EEPROM), flash memory is nonvolatile and thus can maintain its contents even without power.

However, flash memory is not standard EEPROM. Standard EEPROMs are differentiated from flash memory because they can be erased and reprogrammed on an individual byte or word basis while flash memory can be programmed on a byte or word basis, but is generally erased on a block basis. Although standard EEPROMs may appear to be more versatile, their functionality requires two transistors to hold one bit of data. In contrast, flash memory requires only one transistor to hold one bit of data, which results in a lower cost per bit. As flash memory costs far less than EEPROM, it has become the dominant technology wherever a significant amount of non-volatile, solid-state storage is needed.

Exemplary applications of flash memory include digital audio players, digital cameras, digital video recorders, and mobile phones. Flash memory is also used in USB flash drives, which are used for general storage and transfer of data between computers. Also, flash memory is gaining popularity in the gaming market, where low-cost fast-loading memory in the order of a few hundred megabytes is required, such as in game cartridges. Additionally, flash memory is applicable to cellular handsets, smartphones, personal digital assistants, set-top boxes, digital video recorders, networking and telecommunication equipments, printers, computer peripherals, automotive navigation devices, portable multimedia devices, and gaming systems.

As flash memory is a type of non-volatile memory, it does not need power to maintain the information stored in the chip. In addition, flash memory offers fast read access times and better shock resistance than traditional hard disks. These characteristics explain the popularity of flash memory for applications such as storage on battery-powered devices (e.g., cellular phones, mobile phones, IP phones, wireless phones, etc.). Since flash memory is widely used in such devices, and users would desire the devices to have as large a storage capacity as possible, an increase in memory density would be advantageous. Users would also benefit from reduced memory read time and reduced cost.

FIG. 9 shows an exemplary system 3100 in accordance with an embodiment of the invention. System 3100 is well-suited for a number of applications, including digital audio players, digital cameras, digital video recorders, mobile phones, game cartridges, smartphones, personal digital assistants, set-top boxes, networking and telecommunication equipments, printers, computer peripherals, automotive navigation devices, portable multimedia devices, gaming systems, and the like. The system 3100 includes a processor 3102 that pertains to a microprocessor or controller for controlling the overall operation of the system 3100. The system 3100 also includes flash memory 3130. In the present embodiment, the flash memory 3130 may include: a stack formed over a substrate, the stack having a gate oxide layer and an overlying polycrystalline silicon layer, the stack having first and second undercut regions formed under the polycrystalline silicon layer and adjacent to the gate oxide layer; a first charge storage element formed in the first undercut region; and a second charge storage element formed in the second undercut region. The flash memory 3130 may also include other features of a memory cell as described above. According to various embodiments, it is possible to provide a semiconductor device, such as flash memory, such that the memory cells therein each have two physically separated charge storage nodes. As a result, the flash memory 3130 can be manufactured in much smaller packages and much smaller geometries. This decreased size for the flash memory translates into decreased size for various devices, such as personal digital assistants, set-top boxes, digital video recorders, networking and telecommunication equipments, printers, computer peripherals, automotive navigation devices, gaming systems, mobile phones, cellular phones, internet protocol phones, and/or wireless phones.

In the case where the system 3100 is a portable media player. The system 3100 stores media data pertaining to media assets in a file system 3104 and a cache 3106. The file system 3104 is, typically, a storage medium or a plurality of storage media, such as disks, memory cells, and the like. The file system 3104 typically provides high capacity storage capability for the system 3100.

The system 3100 may also include a cache 3106. The cache 3106 is, for example, Random-Access Memory (RAM) provided by semiconductor memory. The relative access time to the cache 3106 is substantially shorter than for the file system 3104. However, the cache 3106 does not have the large storage capacity of the file system 3104. Further, the file system 3104, when active, consumes more power than does the cache 3106. The power consumption is particularly important when the system 3100 is a portable media player that is powered by a battery (not shown). The system 3100 also includes a RAM 3122 and a Read-Only Memory (ROM) 3120. The ROM 3120 can store programs, utilities or processes to be executed in a non-volatile manner. The RAM 3122 provides volatile data storage, such as for the cache 3106.

The system 3100 also includes a user input device 3108 that allows a user of the system 3100 to interact with the system 3100. For example, the user input device 3108 can take a variety of forms, such as a button, keypad, dial, etc. Still further, the system 3100 includes a display 3110 (screen display) that can be controlled by the processor 3102 to display information to the user. A data bus 3124 can facilitate data transfer between at least the file system 3104, the cache 3106, the processor 3102, and the CODEC 3112. The system 3100 also includes a bus interface 3116 that couples to a data link 3118. The data link 3118 allows the system 3100 to couple to a host computer.

In one embodiment, the system 3100 serves to store a plurality of media assets (e.g., songs, photos, video, etc.) in the file system 3104. When a user desires to have the media player play/display a particular media item, a list of available media assets is displayed on the display 3110. Then, using the user input device 3108, a user can select one of the available media assets. The processor 3102, upon receiving a selection of a particular media item, supplies the media data (e.g., audio file, graphic file, video file, etc.) for the particular media item to a coder/decoder (CODEC) 3110.

The CODEC 3110 then produces analog output signals for a speaker 3114 or a display 3110. The speaker 3114 can be a speaker internal to the system 3100 or external to the system 3100. For example, headphones or earphones that connect to the system 3100 would be considered an external speaker.

In a particular embodiment, the available media assets are arranged in a hierarchical manner based upon a selected number and type of groupings appropriate to the available media assets. For example, in the case where the system 3100 is an MP3-type media player, the available media assets take the form of MP3 files (each of which corresponds to a digitally encoded song or other audio rendition) stored at least in part in the file system 3104. The available media assets (or in this case, songs) can be grouped in any manner deemed appropriate. In one arrangement, the songs can be arranged hierarchically as a list of music genres at a first level, a list of artists associated with each genre at a second level, a list of albums for each artist listed in the second level at a third level, while at a fourth level a list of songs for each album listed in the third level, and so on. It is to be understood that the present invention is not limited in its application to the above-described embodiments. Needless to say, various modifications and variations of the present invention may be made without departing from the spirit and scope of the present invention.

Also, as mentioned above, flash memory is applicable to a variety of devices other than portable media devices. For instance, flash memory can be utilized in personal digital assistants, set-top boxes, digital video recorders, networking and telecommunication equipments, printers, computer peripherals, automotive navigation devices, and gaming systems.

FIG. 14 illustrates advantages of memory cells according to one embodiment (solid line) over conventional memory cell designs (dashed line). As shown in FIG. 14, for a given channel length (e.g., L1), the effect of program disturb in embodiments is much less than in conventional designs. Moreover, the effect of decreasing channel length (e.g., L2 vs. L1) is less significant with respect to the embodiment depicted as compared to conventional designs. Thus, embodiments provide for dual storage node memory cells with physical separation of the storage nodes by an insulator. Such separation of the storage nodes greatly reduces program disturb between the two storage nodes, which is a critical issue as process geometries continue to decrease.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A method of fabricating spaced storage nodes on a surface of a substrate between two adjacent bit lines, comprising:
forming spaced stacks of gate silicon oxide and overlying polycrystalline silicon on the surface of the semiconductor substrate between adjacent bit lines;
forming first and second undercut regions in the gate silicon oxide; and
forming first and second charge storage elements in the first and second undercut regions respectively.

2. The method as recited in claim 1 wherein forming the first and second undercut regions comprises:
selectively etching the gate silicon oxide under the polycrystalline silicon to create the first and second undercut regions under the polycrystalline silicon and adjacent to the remaining gate silicon oxide.

3. The method is recited in claim 2 wherein the selective etching is selected from the group consisting of a diluted HF etch and a chemical oxide removal (COR) etch.

4. The method as recited in claim 1 wherein forming the first and second charge storage elements comprises:
forming a tunnel oxide layer on the substrate and on the exposed gate polycrystalline silicon;
forming a layer of charge trapping material over the tunnel oxide layer sufficient to fill the remainder of the first and second undercut regions;
removing the charge trapping material except in the first and second undercut regions; and
forming silicon oxide sidewall spacers on the stacks.

5. The method as recited in claim 4 wherein the charge trapping material is selected from the group consisting of silicon nitride, silicon rich nitride, polycrystalline silicon, and high-K material.

6. The method as recited in claim 4 wherein the removing of the charge trapping material is performed by oxidation.

7. The method as recited in claim 4 wherein the removing of the charge trapping material is performed by etch.

8. The method as recited in claim 1 further comprising:
forming bit lines in the semiconductor substrate using the stacks and the sidewall spacers as a mask.

9. The method as recited in claim 1 further comprising:
filling space between the stacks with silicon oxide filler; and
forming word lines over the silicon oxide filler and the stacks.

10. The method as recited in claim 1 wherein the gate silicon oxide has a thickness of about 20-500 angstroms.

11. A memory cell comprising:
a stack formed over a substrate, the stack having a gate oxide layer and an overlying polycrystalline silicon layer, the stack having first and second undercut regions formed under the polycrystalline silicon layer and adjacent to the gate oxide layer;
a first charge storage element formed in the first undercut region; and
a second charge storage element formed in the second undercut region.

12. The memory cell as recited in claim 11 further comprising:
a tunnel oxide layer formed over the substrate and on the exposed portions of the polycrystalline silicon layer;
a first charge trapping region in the remainder of the first undercut region, wherein the first charge storage element comprises the first charge trapping region and portions of the tunnel oxide layer under the first undercut region;
a second charge trapping region in the remainder of the second undercut region, wherein the second charge storage element comprises the second charge trapping region and portions of the tunnel oxide layer under the second undercut region; and
silicon oxide sidewall spacers formed over the tunnel oxide layer and the first and second charge trapping regions.

13. The memory cell as recited in claim 12 wherein the tunnel oxide layer has a thickness of about 10-100 angstroms.

14. The memory cell as recited in claim 12 wherein the first and second charge trapping regions comprise a material selected from the group consisting of silicon nitride, silicon rich nitride, polycrystalline silicon, and high-K material.

15. The memory cell as recited in claim 11 further comprising:
silicon oxide filler formed in space between adjacent stacks; and
word lines formed over the silicon oxide filler and the stacks.

16. The memory cell as recited in claim 11 wherein the gate oxide layer has a thickness of about 20-500 angstroms.

17. The memory cell as recited in claim 11 wherein the first and second undercut regions have widths of about 50-500 angstroms.

18. The memory cell as recited in claim 11 wherein the polycrystalline silicon layer has a thickness of about 200-2000 angstroms.

19. A system comprising:
a processor;
a cache;
a user input component; and
a flash memory having at least one memory cell comprising:
a stack formed over a substrate, the stack having a gate oxide layer and an overlying polycrystalline silicon layer, the stack having first and second undercut regions formed under the polycrystalline silicon layer and adjacent to the gate oxide layer;
a first charge storage element formed in the first undercut region; and
a second charge storage element formed in the second undercut region.

20. The portable system as recited in claim 19 wherein the system is selected from the group consisting of a portable music player and a portable video player.
